(19) United States
(12) Patent Application Publication
(10) Pub. No.: US 2026/0343803 A1
(43) Pub. Date: Oct. 29, 2026

(54) COOLING STRUCTURE OF A COOLER THROUGH WHICH FLUID CAN FLOW

(71) Applicant: Robert Bosch GmbH, Stuttgart (DE)

(72) Inventors: Daniel Michael Stehlik, Moessingen (DE); Valentin Ruedenauer, Reutlingen (DE); Max Florian Beck, Vaihingen An Der Enz (DE); Tobias Hoppe, Kuppenheim (DE)

(21) Appl. No.: 19/124,346

(22) PCT Filed: Oct. 24, 2023
(86) PCT No.: PCT/EP2023/079578

§ 371 Date: Apr. 25, 2025

(30) Foreign Application Priority Data
Nov. 8, 2022 (DE) 10 2022 211 780.8

(51) Int. Cl. H05K 7/20

(52) U.S. Cl. CPC H05K 7/20272; H05K 7/20927

(57) ABSTRACT

The present invention relates to a cooling structure (1) of a cooler (100) through which fluid can flow, the cooling structure being formed from a U-profile (10) which repeats periodically extending in a repetition direction (501) and which comprises wavy limbs (15) extending in a longitudinal direction (502) of the cooling structure (1) and formed according to a trigonometric function (13).

### BACKGROUND

The present invention relates to a cooling structure of a cooler through which fluid can flow for cooling power electronics, a method for manufacturing a cooling structure of this type and a cooler through which fluid can flow. Furthermore, the invention relates to a power electronics assembly having a cooler of this type and power electronics.

It is known that power semiconductors of power electronics carry high electrical currents. Together with switching losses, the resulting conduction losses are the cause of high heat dissipation, which must be dissipated over a very small area. The maximum permissible semiconductor temperature is critical to failure, which is why minimizing the thermal resistance between the semiconductor and the coolant is of central importance. For efficient cooling, the power substrates are applied to coolers through which fluid can flow. These coolers are made of aluminum, AlSiC, or copper alloys. Pins or fins are located inside the cooler to increase the heat transfer surface and intensify the heat transfer. In order to achieve a low thermal resistance between a power substrate, in particular an AMB/DBC power substrate (AMB: active metal braze; DBC: direct copper bonding), and the cooler, the power substrate is joined to the cooler by means of a soft soldering process or, optionally, a sintering process. For this purpose, these coolers can be surface-coated with materials suitable for a soft soldering process or a sintering process. In automotive engineering, aluminum coolers, also AlSiC or copper coolers, which consist of a plurality of components that are joined in particular by a brazing process, are frequently known.

### SUMMARY

The cooling structure according to the invention of a cooler through which fluid can flow has the advantage of a good balance between the heat transfer performance achieved from the cooling structure to a fluid used as a coolant and the pressure drop caused by the cooling structure when the cooling structure is used in such a cooler and the fluid flows through the cooler. This is achieved by a cooling structure of a cooler through which fluid can flow formed from a U-profile which repeats periodically in a repetition direction and comprises wavy limbs. The wavy limbs extend in a longitudinal direction of the cooling structure and are formed according to a trigonometric function. In other words, the wavy limbs are each in the form of a trigonometric function. As the wavy limbs are parts of the U-profile that repeats itself, all the wavy limbs of the cooling structure are advantageously of the same shape. The repetition of the U-profile in the repetition direction advantageously results in a one-piece continuous profile, which can in particular be referred to as a shaft profile in the context of the invention. The wavy limbs of the cooling structure cause a turbulent flow of the fluid used as coolant, which leads to increased heat dissipation with an acceptable pressure drop caused due to the wavy shape of the limbs. The cooling structure according to the invention is therefore particularly suitable for use in coolers through which fluid flows, in particular high-power coolers, for power electronic applications.

Preferably, the U-profile is repeated an integer or non-integer number of times. In other words, for an integer number of repetitions of the U-profile, the cooling structure corresponds to an integer multiple of the periodically repeating profile. On the other hand, a non-integer number of repetitions means that the cooling structure is not an integer multiple of the U-profile which repeats periodically. How many times the profile repeats advantageously depends on a width of the power electronics, which is to be cooled by a cooler through which fluid can flow comprising the cooling structure. For example, the U-profile may repeat 5 times in the repetition direction. The cooling structure 5 comprises repetitions of the U-profile or in other words 5 U-profiles, which are connected to each other in such a way that a one-piece continuous wave profile is produced.

Preferably, the cooling structure has a width direction and a height direction adjacent to the longitudinal direction. The repetition direction preferably corresponds to the width direction. The longitudinal direction may preferably be perpendicular or inclined to the repetition direction. The height direction is perpendicular to the width direction and the longitudinal direction.

Preferably, the longitudinal direction is the direction that is parallel to a line connecting the geometric center of the cross-section of the U-profile at a first end of the cooling structure to the geometric center of the cross-section of the U-profile at a second end of the cooling structure.

Preferably, the repetition direction is parallel to a Y-axis of a space-fixed coordinate system and the height direction is parallel to a Z-axis of the space-fixed coordinate system. The longitudinal direction may preferably be parallel or inclined to an X-axis of the space-fixed coordinate system. The X-axis, Y-axis, and Z-axis of the space-fixed coordinate system are perpendicular to each other. In other words, the space-fixed coordinate system is a Cartesian coordinate system in three-dimensional space.

The longitudinal direction may preferably be the direction in which the cooling structure has its longest dimension. The longitudinal direction of the cooling structure preferably corresponds to an extension direction of the repeating U-profile.

For example, the trigonometric function may be a sinusoidal function. In the context of the invention, a limb may also be referred to as a side wall.

Preferably, a height of the U-profile which repeats periodically is from 3.7 mm to 4.5 mm, more preferably 4 mm. The height of the U-profile corresponds to the dimension of the U-profile in the height direction that is perpendicular to the repetition direction. Advantageously, the height of the U-profile corresponds to the height of the cooling structure. That is in particular to say that the cooling structure has a constant height.

Preferably, a period of the U-profile which repeats periodically is from 2 mm to 3.1 mm, more preferably 2.8 mm. It is to be understood that the period of the U-profile which repeats periodically is a dimension in the repetition direction. It is further to be understood that the period between a first end (side end) and a second end (side end) of the cooling structure is constant in the repetition direction. That is to say, in particular, that the U-profile which repeats periodically repeats itself regularly.

Preferably, a period of the trigonometric function is from 5.1 mm to 6 mm, more preferably 5.5 mm. It is to be understood that the period of the trigonometric function is a dimension in the longitudinal direction.

Preferably, an amplitude of the trigonometric function is from 0.25 mm to 0.8 mm, more preferably 0.4 mm. The amplitude of the trigonometric function corresponds to the greatest distance of the trigonometric function to the resting position of the trigonometric function, which is in the middle between the highest and the lowest function value of the trigonometric function.

Preferably, a material thickness of the U-profile which repeats periodically is from 0.2 mm to 0.4 mm, more preferably 0.3 mm. In other words, preferably the material thickness of the wavy limbs is from 0.2 mm to 0.4 mm, more preferably 0.3 mm. The profile which repeats periodically advantageously has a constant material thickness.

Each of the previously stated ranges of values contributes individually to a good balance between the heat transfer performance achieved and the pressure drop caused. The particularly preferred value of a respective parameter from the above-mentioned parameters (height of the U-profile which repeats periodically, period of the U-profile which repeats periodically, period of the trigonometric function, amplitude of the trigonometric function, material thickness of the profile which repeats periodically) achieves the optimal balance between the achieved heat transfer performance and the pressure drop caused with respect to the respective parameter.

According to a particularly preferred exemplary embodiment of the invention, the height of the U-profile which repeats periodically is 4 mm, the period of trigonometric function is 5.5 mm, the amplitude of the trigonometric function is 0.8 mm, and the material thickness of the U-profile which repeats periodically is 0.3 mm. This configuration of the cooling structure has the advantage of an optimal balance between the achieved heat transfer efficiency and the pressure drop caused.

Preferably, a part of the cooling structure comprising two (adjacent) limbs, two first connection regions and a second connection region can be referred to as a U-profile in the context of the invention. The second connection region connects the two limbs to each other, wherein the first connection regions connects the U-profile to an adjacent U-profile (repeat of the U-profile) respectively. The first connection regions and the second connection region are preferably parallel to a plane that is perpendicular to the height direction. In an installed state of the cooling structure in a cooler through which fluid can flow, the first connection regions are closer to the power electronics than the second connection region.

The repeating U-profile is preferably a rounded profile. That is in particular to say that a transition between a limb and a connection region (first or second connecting region) has a rounding. In other words, a limb transitions into the first connection region or second connection region with a rounding radius. However, it is also possible that the repeating U-profile is an edged profile, i.e., without rounding at the specified locations.

According to one embodiment of the invention, the cooling structure can be configured such that all cross-sections of the cooling structure have an equally large cross-section in a section with a plane whose normal vector is perpendicular to the repetition direction. Alternatively, the cooling structure can be configured such that not all cross-sections of the cooling structure have an equally large cross-section in a section with a plane whose normal vector is perpendicular to the repetition direction.

The cooling structure may be manufactured by means of a punching, roll forming or extrusion process.

The cooling structure in the context of the present invention is preferably understood as a surface-enhancing, flow-conducting and heat-transfer-increasing structure.

The cooling structure may also be referred to in the context of the invention as a cooling fin structure, since a cooling fin is formed by the repeating U-profile. The cooling structure may in particular also be referred to as a turbulator, since it causes a turbulent flow of a flowing fluid, as already described above.

A flow direction corresponds in particular to a main flow direction of a fluid used as a coolant, which flows through openings formed by the cooling structure. In particular, the main flow direction is in this case the direction in which the fluid mainly flows, i.e., the direction in which a velocity component of the fluid is greater than a velocity component of the fluid in a direction perpendicular to the main flow direction. The main flow direction may preferably correspond to a direction in which the fluid enters the cooler, through which fluid can flow.

The cooling structure is preferably at least partially, in particular completely, made of a material and/or coated with a material that has a thermal conductivity coefficient that is greater than 200 W/(m·K). Advantageously, the cooling structure may be, at least partially, in particular completely, made of aluminum or coated with aluminum.

The cooler through which fluid can flow may also serve to cool components other than the power electronics that are located on the cooler in a power electronics assembly, such as EMC filters, capacitors, or power buses.

Furthermore, the invention relates to a cooler through which fluid can flow for cooling power electronics. The cooler through which fluid can flow comprises a cooling structure described above, a first metal part, and a second metal part. The first metal part and the second metal part are connected to each other and define a cooling channel in which the cooling structure is arranged. A cooling channel direction, i.e. the direction in which the cooling channel extends, is preferably parallel or inclined to the longitudinal direction of the cooling structure or parallel to the longitudinal axis of the above-mentioned space-fixed coordinate system.

The first metal part and the second metal part advantageously form a housing that defines, in particular encloses, the cooling channel. The cooling channel corresponds in particular to an interior of the housing. Preferably, an inlet and an outlet for a fluid used as a coolant are located directly on the housing.

The first metal part and the second metal part may advantageously be directly or indirectly connected to one another. In particular, a direct connection means that between the first metal part and the second metal part there is only one connecting layer, in particular a bonding hard solder layer. An indirect connection means in particular that at least one further metal part is provided between the first metal part and the second metal part, wherein the first metal part is connected to the second metal part via the at least one further metal part and a connecting layer, in particular a bonding hard solder layer, between the first metal part and the at least one further metal part, and a connecting layer, in particular a bonding hard solder layer, between the second metal part and the at least one further metal part.

The first metal part and/or the second metal part is/are preferably configured as sheet metal(s).

Another aspect of the present invention relates to a power electronics assembly comprising a cooler through which fluid can flow previously described for cooling power electronics, and power electronics arranged on the cooler through which fluid can flow. Heat generated by the power electronics during operation may be efficiently removed by the cooler through which fluid can flow.

The power electronics may preferably comprise at least one power module having a power substrate. The at least one power module is attached to/on the first metal part of the cooler through which fluid can flow by means of the power substrate.

The power substrate may preferably be made from copper and/or ceramic (AMB/DBC power substrate; AMB: active metal braze; DBC: direct copper bonding).

For the purpose of a low thermal resistance between the power substrate and the cooler, in particular the first metal part, the power substrate can preferably be joined to the cooler, in particular the first metal part, by means of a soft soldering process, optionally also a sintering process. This means that the power module is preferably joined to the cooler through which fluid can flow or the first metal part by means of a layer generated by a soft soldering process or a sintering process, which is thus a soft soldering layer or a sintering layer.

The power module preferably comprises one or more power semiconductors. The power semiconductor(s) generate heat during operation of the power module, which may be dissipated by the cooler.

Furthermore, the invention relates to a method for manufacturing a cooling structure of a cooler through which fluid can flow, in particular the previously described cooling structure, the cooling structure being formed from a U-profile which repeats periodically extending in a repetition direction and which comprises wavy limbs extending in a longitudinal direction of the cooling structure and formed according to a trigonometric function. The method comprises the step of extruding the repeating U-profile along the trigonometric function in an extrusion direction, which is perpendicular to the repetition direction or is tangential to the trigonometric function or lies between these two orientations. The formulation “between these two orientations” means in particular, that the extrusion direction is between a respective tangent of the trigonometric function and a perpendicular to the repetition direction.

The formulation that the U-profile is extruded along the trigonometric function preferably means that the geometric center of the U-profile moves along/on a mapping of the geometrical function.

### BRIEF DESCRIPTION OF THE DRAWINGS

In the following, exemplary embodiments of the invention are described in detail with reference to the accompanying drawings. The drawings show:

FIG. 1 is a schematic simplified perspective sectional view of a power electronics assembly according to the invention comprising power electronics and a cooler through which fluid can flow according to a first exemplary embodiment of the invention,

FIG. 2 is a simplified schematic perspective view of the cooling structure according to the first exemplary embodiment of the invention,

FIG. 3 is a simplified sketch for explaining a manufacturing process according to the invention of the cooling structure according to the first exemplary embodiment, in which the cooling structure is shown in a plan view,

FIG. 4 is a simplified sketch for explaining a manufacturing process of a cooling structure according to a second exemplary embodiment, in which the cooling structure is shown in a plan view, and

FIG. 5 is a schematic simplified sectional view of a power electronics assembly according to the invention comprising power electronics and a cooler according to a third exemplary embodiment which comprises the cooling structure from FIG. 2.

### DETAILED DESCRIPTION

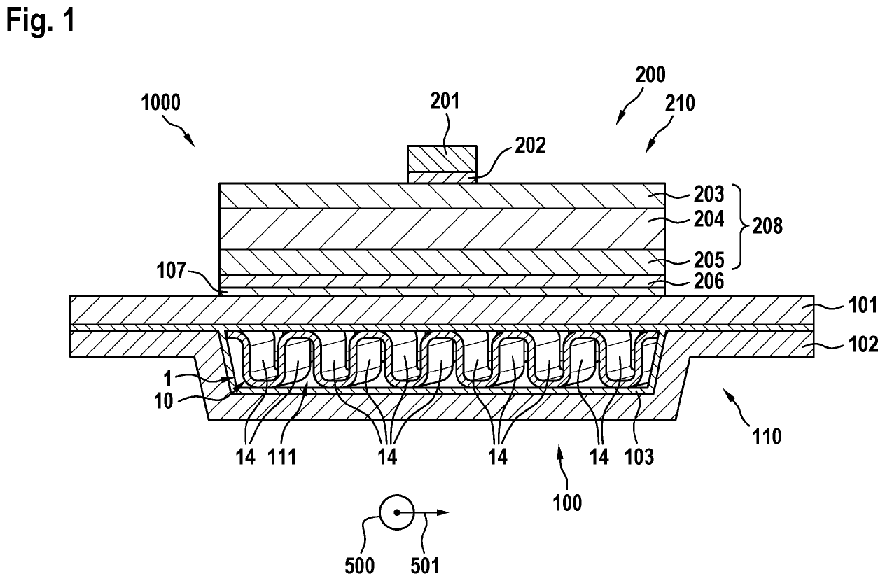

Referring to FIGS. 1 through 3, a power electronics assembly 1000 according to the invention comprising power electronics 200 and a cooler 100 with a cooling structure 1 according to a first exemplary embodiment of the invention is described below.

As shown in FIG. 1, the power electronics 200 comprises a power module 210, which can also be referred to as a power electronics unit. The power electronics module 210 comprises a printed circuit board 204, conductor tracks 203, 205 and power semiconductors 201. The conductor tracks 203, 205 are designed in particular as copper conductor tracks, whereby the printed circuit board 204 is preferably made of ceramic.

The power semiconductors 201 are applied to the trace 203 by a layer 202. In particular, the layer 202 is in this case designed as a solder or sintered layer.

The conductor tracks 203, 205 together with the printed circuit board 204 form a power substrate 208. The power substrate 208 is joined to the cooler 100, in particular to a first metal part 101 of a housing 110 of the cooler 100, by means of a layer 206 produced by a soft soldering process or a sintering process, which is thus correspondingly a soft soldering layer or sintering layer.

The housing 110 of the cooler 100 further comprises a second metal part 102, which is connected to the first metal part 101 by means of a layer (bonding layer) 103, which is in particular designed as a brazing solder layer. Both the first metal part 101 and the second metal part 102 are preferably aluminum parts.

FIG. 1 also shows that the first metal part 101 is an upper part and the second metal part 102 is a lower part of the housing 110. The first metal part 101 faces the power module 210, wherein the second metal part 102 faces away from the power module 210. Furthermore, in this exemplary embodiment, the first metal part 101 is plate-shaped, whereby the second metal part 102 comprises a plate-shaped region and a trapezoidal region in cross-section. However, it is also possible for the first metal part 101 and the second metal part 102 to comprise other shapes. The second metal part 102 may advantageously be produced by means of a deep-drawing process.

A mediation layer 107 is advantageously located between the layer 206 and the cooler 100 (in particular the first metal part 101), which layer is firmly connected to the first metal part 101 and enables wetting of the layer 206. The mediation layer 107 is an optional feature of the power electronics assembly 1000 and can in particular be considered either as a separate part or as part of the housing 110 of the cooler 100.

The first metal part 101 and the second metal part 102, which form the housing 110 of the cooler 100 when joined together, define an interior space which serves as the cooling channel 111 of the cooler 100.

The cooling structure 1 is arranged in the cooling channel 111, which serves as a surface-enlarging, flow-guiding and heat-transfer-enhancing structure for a fluid used as a coolant. The cooling structure 1 is advantageously joined to the first metal part 101 and second metal part 102 by means of the layer 103.

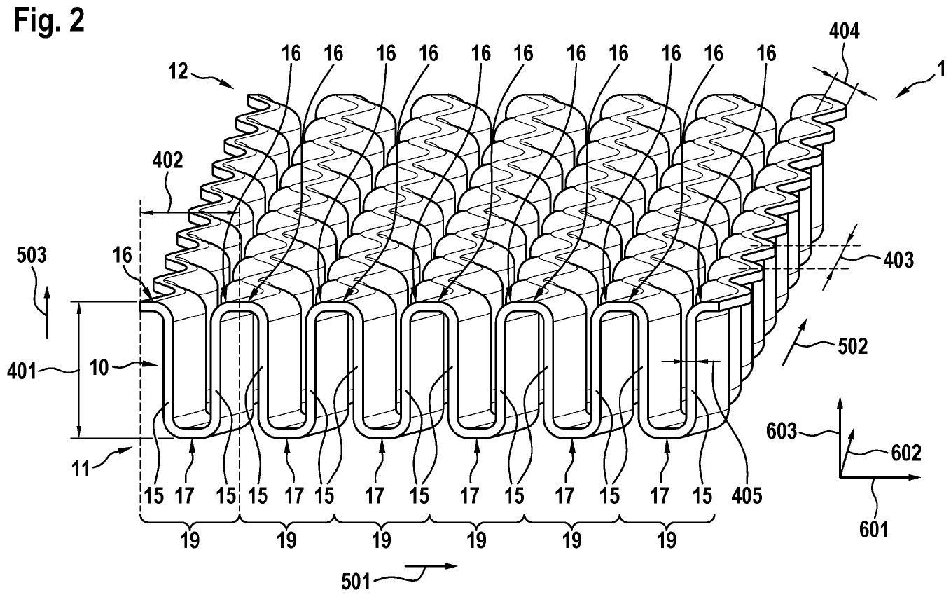

As can be seen from FIGS. 1 and 2, the cooling structure 1 is formed from a U-profile 10 which repeats periodically in a repetition direction 501. The repetition direction 501 is perpendicular to a flow direction 500 and corresponds in particular to a width direction of the cooler 100. The flow direction 500 corresponds to a main flow direction of a fluid used as a coolant when it flows through the cooling channel 111, in particular through through-openings 14 (FIG. 1), which are formed by the repeating U-profile 10. The flow direction 500 further corresponds to a cooling channel direction which is the direction in which the cooling channel 11 extends substantially. In this exemplary embodiment, the U-profile 10 repeats 6 times so that six repetitions 19 of the U-profile 10 or, in other words six interconnected U-profiles, are provided in the cooling structure 1.

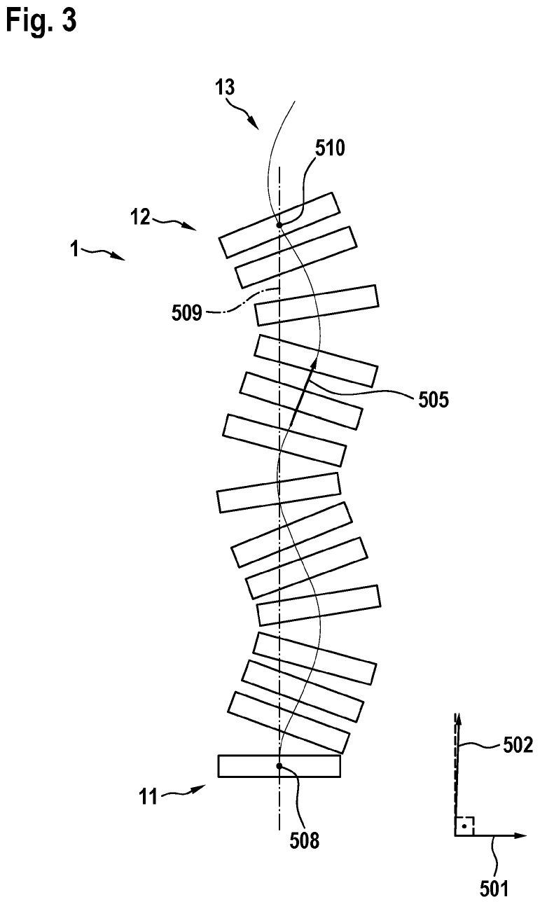

In FIG. 2, a longitudinal direction 502 and a height direction 503 are further drawn in addition to the repetition direction 501. The longitudinal direction 502 is inclined (i.e., not perpendicular) to the repetition direction 501 in this exemplary embodiment. The height direction 503 is perpendicular to the repetition direction 501 and the longitudinal direction 502. As can be seen from FIG. 3, the longitudinal direction 502 is in particular the direction that is parallel to a line 509 connecting the geometric center 508 of the cross-section of the U-profile 10 at a first end 11 of the cooling structure 1 to the geometric center 510 of the cross-section of the U-profile 10 at a second end 12 of the cooling structure 1.

In FIG. 2, a space-fixed Cartesian three-dimensional coordinate system is further drawn. The repetition direction 501 is parallel to a Y-axis 601 of the coordinate system and the height direction 503 is parallel to a Z-axis of the coordinate system 603. The longitudinal direction 502 is inclined to an X-axis 602 of the coordinate system.

Referring to FIGS. 1 and 2, the repeating U-profile 10 comprises wavy limbs 15, first connection regions 16 and second connection regions 17. The first connection regions 16 connect two adjacent wavy limbs 15 of adjacent repetitions 19 of the U-profile 10 to each other in an upper region of the wavy limbs 15, wherein the second connection regions 17 connect adjacent limbs 15 of the same repetition 19 of the U-profile 10 to each other in a lower region of the limbs 15. The first connection regions 16 are closer to the power electronics 200 than the second connection regions 17. In particular, the wavy limbs 15 of each repetition 19 are connected together by means of a second connection region 16. Furthermore, each repetition 19 of the U-profile 10 is connected to the adjacent repetition of the U-profile 10, in particular a wavy limb 15 of each repetition 19 of the U-profile 10 with the corresponding wavy limb 15 of the adjacent repetition 19 of the U-profile 10, by means of the corresponding first connection regions 16 of the two repetitions 19.

In this exemplary embodiment, the repeating profile 10 is rounded. That is to say, each limb 15 transitions with a rounding radius into the corresponding first connection region 16 and the corresponding second connection region 17.

To allow a good balance between a heat capacity transfer between the fluid used as the coolant and the cooling structure 1 and a pressure drop caused by the cooling structure 1, the cooling structure 1 is configured as follows:

A height 401 of the repeating U-profile 10 or cooling structure 1 is from 3.7 mm to 4.5 mm, more preferably 4 mm. A period 402 of the U-profile which repeats periodically 10 is from 2 mm to 3.1 mm, more preferably 2.8 mm. A period 403 of the trigonometric function 13 is from 5.1 mm to 6 mm, more preferably 5.5 mm. Furthermore, an amplitude 404 of the trigonometric function 13 is from 0.25 mm to 0.8 mm, more preferably 0.4 mm. Furthermore, a material thickness 405 of the U-profile which repeats periodically or cooling structure 1 is from 0.2 mm to 0.4 mm, more preferably 0.3 mm.

It is noted that a length of the cooling structure 1 is preferably adapted to a length of the power module 10 To support the heat dissipation from the power module 210 by means of the fluid used as the coolant, the cooling structure 1 is at least partially, in particular completely, formed from a material and/or coated with a material having a thermal conductivity coefficient that is greater than 200 W/(m·K). Advantageously, the cooling structure 1 may be, at least partially, in particular completely, made of aluminum or coated with aluminum.

FIG. 3 shows a simplified sketch explaining a method of manufacturing the cooling structure 1 according to the first exemplary embodiment.

In particular, the trigonometric function 13 is shown graphically in FIG. 3. Furthermore, rectangles are drawn, each representing an area of the cooling structure 1 viewed from the top.

According to the manufacturing method, the repeating U-profile 10 may be extruded along the trigonometric function 13 in an extrusion direction 504 that is tangential to the trigonometric function 13. It is noted that the extrusion direction 504 does not have a constant orientation, but always runs tangentially to the trigonometric function 13.

Thus, in this exemplary embodiment, the cooling structure 1 is configured as an extrusion component in which the longitudinal direction 502 is inclined towards the repetition direction 501 (at an angle not equal to 90 degrees).

The cooling structure 1 is configured according to this manufacturing method such that not all cross-sections of the cooling structure 1 have an equally large cross-section in a section with a plane whose normal vector is perpendicular to the repetition direction 501.

The cooling structure 1 and thus also the cooler 100 and the power electronics assembly 1000 according to the present invention are characterized by a good ratio of the thermal performance to the pressure drop caused in the cooling channel 111 due to the described configuration of the repeating U-profile 10.

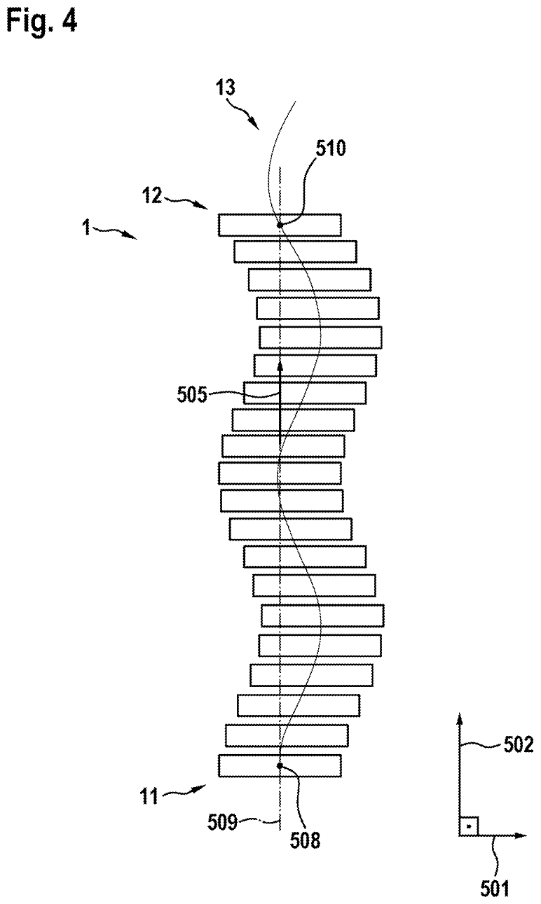

FIG. 4 shows a simplified sketch explaining a method for manufacturing the cooling structure 1 according to a second exemplary embodiment.

Analogously to FIG. 3, the trigonometric function 13 is shown graphically in FIG. 4. Furthermore, rectangles are drawn, each representing an area of the cooling structure 1 viewed from the top.

To manufacture the cooling structure 1 according to the second exemplary embodiment, the repeating U-profile 10 can be extruded along the trigonometric function 13 in an extrusion direction 504, which is not tangential to the trigonometric function 13, in contrast to the method for manufacturing the cooling structure 1 according to the first design example. It is perpendicular to the repetition direction 501 or, in other words, parallel to the cooling channel direction, Here, the extrusion direction 504 is (always) parallel to the longitudinal direction 502.

The cooling structure 1 is configured according to the manufacturing method, such that all cross-sections of the cooling structure 1 have an equally large cross-section in a section with a plane whose normal vector is perpendicular to the repetition direction 501.

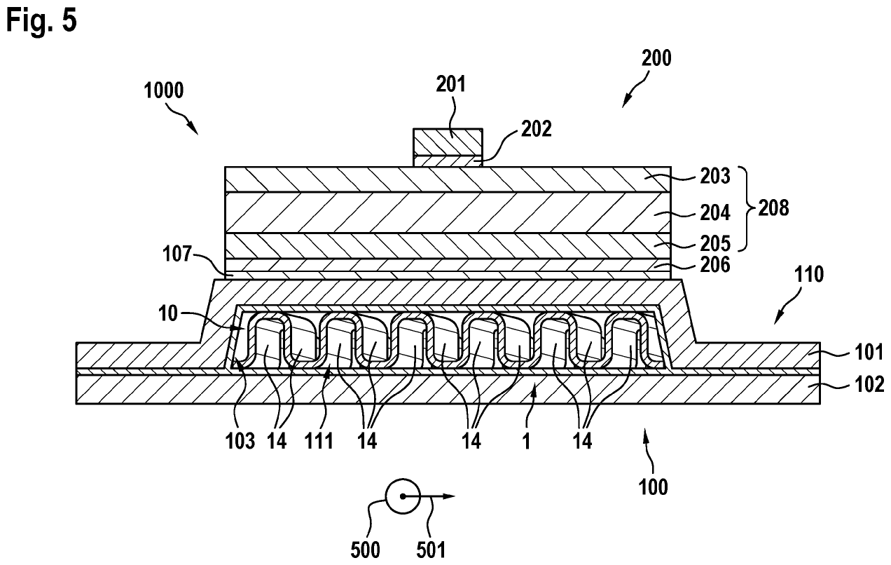

FIG. 5 shows a power electronics assembly 1000 according to a third exemplary embodiment of the present invention.

The power electronics assembly 1000 according to the third exemplary embodiment differs from that according to the first exemplary embodiment in that the first metal part 101, which is the upper part and thus faces the power module 210, has a plate-shaped region and a trapezoidal region in cross-section, wherein the second metal part 102, which is the lower part and thus faces the power module 210, is plate-shaped.

This design of the housing 110 can be advantageous in the event of a lack of space in the immediate vicinity of the power module 210.

It should be noted that the housing 110 of the cooler 100 according to the third exemplary embodiment can also be combined with the cooling structure 1 provided by the manufacturing method according to the second exemplary embodiment.

In the exemplary embodiments described above, the power electronics 200 comprise only one power module 210. However, it is possible for the power electronics 200 to have two or more power modules 210. To this end, a corresponding number of cooling structures 1 can be arranged in the cooling channel 111 of the cooler 100, wherein each cooling structure 1 is associated with one of the power modules 210. Please amend the listing of claims as follows:

1. A cooling structure (1) of a cooler (100) through which fluid can flow, the cooling structure being formed from a U-profile which repeats periodically extending in a repetition direction (501) and which comprises wavy limbs (15) extending in a longitudinal direction (502) of the cooling structure (1) and formed according to a trigonometric function (13).

2. The cooling structure (1) according to claim 1, wherein a height (401) of the U-profile (10) which repeats periodically is from 3.7 mm to 4.5 mm.

3. The cooling structure (1) according to claim 1, wherein a period (402) of the U-profile (10) which repeats periodically is from 2 mm to 3.1 mm.

4. The cooling structure (1) according to claim 1, wherein a period (403) of the trigonometric function (13) is from 5.1 mm to 6 mm.

5. The cooling structure (1) according to claim 1, wherein an amplitude (404) of the trigonometric function (13) is from 0.25 mm to 0.8 mm

6. The cooling structure (1) according to claim 1, wherein a material thickness of the U-profile (10) which repeats periodically is from 0.2 mm to 0.4 mm.

7. The cooling structure (1) according to claim 1, wherein the cooling structure (1) is configured such that all cross-sections of the cooling structure (1) have an equally sized cross-section in a section with a plane whose normal vector is perpendicular to the repetition direction (501), or wherein not all cross-sections of the cooling structure (1) have an equally sized cross-section in a section with a plane whose normal vector is perpendicular to the repetition direction (501).

8. A cooler (100) through which fluid can flow for cooling power electronics (200), comprising:
a cooling structure (1) according to claim 1,
a first metal part (101), and
a second metal part (102), wherein the first metal part (101) and the second metal part (102) are connected to one another and define a cooling channel (111) in which the cooling structure (1) is arranged.

9. A power electronics assembly (1000), comprising:
a cooler (100) through which fluid can flow according to claim 8 for cooling a power electronics, and
power electronics (200) arranged on the cooler (100) through which fluid can flow.

10. A method for manufacturing a cooling structure (1) of a cooler (100) through which fluid can flow, the cooling structure being formed from a U-profile (10) which repeats periodically in a repetition direction and which comprises wavy limbs (15) extending in a longitudinal direction of the cooling structure (1) and formed according to a trigonometric function (13), wherein the repeating U-profile (10) is extruded along the trigonometric function (13) in an extrusion direction, which is perpendicular to the repetition direction (501) or tangential to the trigonometric function (13) or between these two orientations.

11. The cooling structure (1) according to claim 2, wherein a height (401) of the U-profile (10) which repeats periodically is 4 mm.

12. The cooling structure (1) according to claim 3, wherein the period (402) of the U-profile (10) which repeats periodically is 2.8 mm.

13. The cooling structure (1) according to claim 4, wherein the period (403) of the trigonometric function (13) is 5.5 mm.

14. The cooling structure (1) according to claim 5, wherein the amplitude (404) of the trigonometric function (13) is 0.4 mm.

15. The cooling structure (1) according to claim 6, wherein the material thickness of the U-profile (10) which repeats periodically is 0.3 mm.
